(19) United States
(12) Patent Application Publication
(10) Pub. No.: US 2003/0082892 A1
(43) Pub. Date: May 1, 2003

(54) Method for reducing the drain coupling ratio of floating gate device

(75) Inventors: Tso-Hung Fan, Taipei (TW); Wen-Jer Tsai, Hua-Lien (TW); Tao-Cheng Lu, Kaohsiung (TW)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: MACRONIX INTERNATIONAL CO., LTD.

(21) Appl. No.: 09/984,900

(22) Filed: Oct. 31, 2001

(51) Int. Cl. H01L 21/425

(52) U.S. Cl. 438/514; 438/527

(57) ABSTRACT

First of all, a semiconductor substrate is provided, wherein the semiconductor substrate has a dielectric layer thereon and two insulated regions that are individually located on the boundary of the semiconductor substrate. Then a first ion implanting process is performed to form an ion-implanting region in the semiconductor substrate between two insulated regions. Next, a second ion implanting process is performed to intensify the ion-implanting region in the semiconductor substrate between two insulated regions. Afterward, a third ion implanting process is performed to intensify again the ion-implanting region in the semiconductor substrate between two insulated regions. Subsequently, floating gates are formed and defined on the dielectric layer. Finally, source/drain regions are formed in the ion implanting region of the semiconductor substrate between the plurality of floating gates from each other by way of using a fourth ion implanting process.

### BACKGROUND OF THE INVENTION

1. Field of the Invention

The present invention relates generally to a method for forming a floating gate devices process, and more particularly to a method for forming a floating gate with lower drain coupling ratio (DCR)

2. Description of the Prior Art

Recent, developments have included various techniques for increasing the density of integration of the semiconductor memory device and decreasing the voltage thereof. Especially, there is an increasing demand for highly integrated non-volatile memory now and in the future. A control gate and a floating gate have long been utilized for forming a flash memory. Electrons are moved onto or removed from the floating gate of a given memory cell in order to program or erase its state. The floating gate is surrounded by an electrically insulated dielectric. Since the floating gate is well insulated, this type of memory device is not volatile; that is, the floating gate retains its charge for an indefinite period without any power being applied to the device. Moreover, if enough electrons are so injected into the floating gate, the conductivity of the channel of the field effect transistor of which the floating gate is a part is changed. Hence, a control gate is coupled with the floating gate through a dielectric layer and acts as a word line to enable reading or writing of a single selected cell in a two-dimensional array of cells.

One type of memory array integrated circuit chip includes elongated, spaced apart source and drain regions formed in a surface of a semiconductor substrate, wherein the source and drain regions form the bit lines of the memory. A two-dimensional array of floating gates has each floating gate positioned in a channel region between adjacent source and drain regions, while the control gate is positioned over each row of floating gates in a direction transverse to the source and drain regions, wherein the control gates are the word lines of the memory array. As shown in FIG. 1A, a conventional flash memory 100 has a floating gate 110 and a control gate 120. Electrons flow through tunnel oxide layer 140 from drain 130 into floating gate 110 by tunnel effect or hot-channel, so as to arise threshold voltage of the flash memory 100 and to save data. Furthermore, electrons flow through tunnel oxide layer 140 from floating gate 110 into source 150 by tunnel effect or hot-channel, so as to decrease threshold voltage of the flash memory 100 and to erase data.

The drain-turn-on leakage (DTOL) is a key issue in conventional floating gate device application. However, when the channel length of floating gate devices or flash memory is scaled down, the drain-turn-on leakage (DTOL) becomes more serious, which is strongly dependent on the drain coupling ratio (DCR). As shown in FIG. 1B, the smaller channel length will induce higher drain coupling ratio (DCR), which is a main cause for the drain-turn-on leakage (DTOL). For example, the drain bias of cell A is about 5V to 8V in conventional floating gate device applications with a drain coupling ratio (DCR) about 10% to 15%, as shown in FIG. 1C. In such condition, the floating gate will be effectively coupled about 0.5V to 1.2V, which will induced a large of the drain-turn-on leakage (DTOL) in unselected cell B. In other words, when the cell A is programmed by way of using the threshold voltage (Vt) about 5V to 8V, the gate voltage (Vg) enters into the cell B about 0.5V to 1.2V, which is due to the capacitance. Wherein the gate voltage (Vg) should be 0V in the idea state when the cell B is predetermined to be not programmed. Hence, a portion of the current is transported into the cell B during programming of cell A, so that a passageway is formed, this phenomenon is the drain-turn-on leakage (DTOL)

On the other hand, when the drain coupling ratio (DCR) gets larger, the floating gate will be coupled to a larger positive potential and increase the drain-turn-on leakage (DTOL) As shown in FIG. 1D, the higher drain coupling ratio (DCR) will enhance the drain-turn-on leakage (DTOL), so that the drain coupling ratio (DCR) is too high in conventional flash memories, which show serious shot channel effect (SCE). Therefore, it is difficult to fabricate highly integrated flash memory with a small channel length.

In accordance with the above description, a new and improved method for forming the flash memory with a small channel length is therefore necessary, so as to raise the yield and quality of the follow-up process.

### SUMMARY OF THE INVENTION

In accordance with the present invention, a method is provided for fabricating highly integrated flash memory that substantially overcomes drawbacks of above mentioned problems raised from the conventional methods.

Accordingly, it is a main object of the present invention to provide a method for fabricating the flash memory with small dimension floating gate device. This invention can reduce the drain coupling ratio (DCR) by increasing the floating gate device's channel doping, so as to decrease the drain-turn-on leakage (DTOL) Furthermore, this invention can also fabricate highly integrated non-volatile memory by significantly scaling down the floating gate device, which will be an excellent candidate for next generation highly integrated flash memory. Therefore, the present invention can correspond to industrial economic effect, and the present invention is appropriate for deep sub-micron technology to provide the semiconductor devices.

In accordance with the present invention, a new method for forming semiconductor devices is disclosed. First of all, a semiconductor substrate is provided, wherein the semiconductor substrate has a dielectric layer thereon and two insulated regions that are individually located on the boundary of the semiconductor substrate. Then a first ion-implanting process is performed to form an ion-implanting region in the semiconductor substrate between two insulated regions, wherein the first ion-implanting process comprises: a first dopant, such as boron; a first dosage, such as 1E¹³ to 2.5E¹³; and a first energy, such as 150 KeV to 350 KeV. Next, a second ion-implanting process is performed to intensify the ion-implanting region in the semiconductor substrate between two insulated regions, wherein the second ion-implanting process comprises: a second dopant, such as boron; a second dosage, such as 3E¹³ to 6.5E¹³; and a second energy, such as 100 KeV to 150 KeV. Afterward, a third ion-implanting process is performed to intensify again the ion-implanting region in the semiconductor substrate between two insulated regions, wherein the third ion-implanting process comprises: a third dopant with boron-based, such as boron or boron fluoride (BF₂); a third dosage, such as 5E¹² to 25E¹²; and a third energy, such as 10 KeV to 70 KeV. Furthermore, the third ion-implanting process is used to adjust the threshold voltage (Vt). Subsequently, floating gates are formed and defined on the dielectric layer. Finally, source/drain regions are formed in the ion-implanting region of the semiconductor substrate between the floating gates from each other by way of using a fourth ion-implanting process. Accordingly, this invention can form the floating gate devices with a small drain coupling ratio (DCR).

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A shows cross-sectional views illustrative of structure in the conventional flash memory;

FIG. 1B shows the relational diagram between the drain coupling ratio and the channel length of the floating gate;

FIG. 1C shows view illustrative of the drain-turn-on leakage;

FIG. 1D shows the relational diagram between the drain coupling ratio and the drain-turn-on leakage;

FIGS. 2A to 2C show cross-sectional views illustrative of various stages in the fabrication of ion-implanting region with heavy dopant in accordance with the first embodiment of the present invention;

FIGS. 3A to 3D show cross-sectional views illustrative of various stages in the fabrication of floating gate in accordance with the second embodiment of the present invention;

FIGS. 4A to 4F show cross-sectional views illustrative of various stages in the fabrication of floating gate of the flash memory in accordance with the second embodiment of the present invention; and

FIG. 5 shows the relational diagram between the drain coupling ratio and the channel doping.

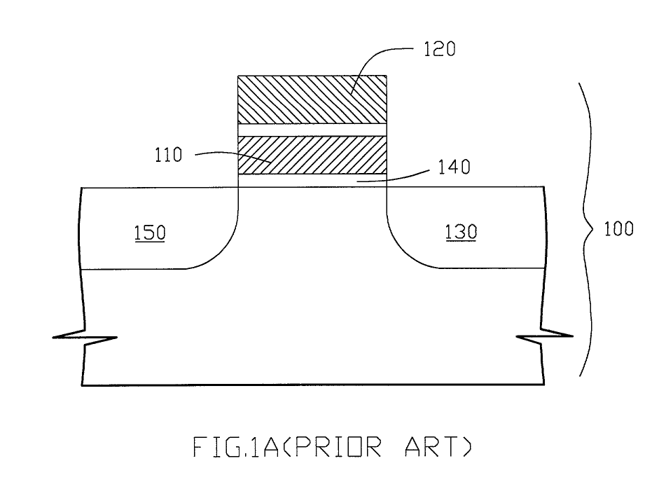

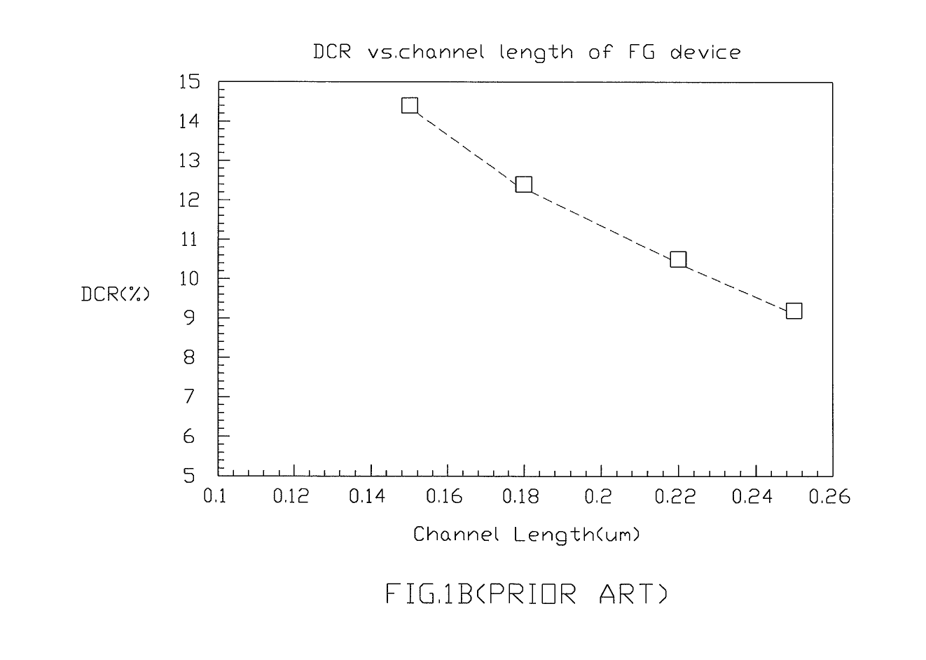

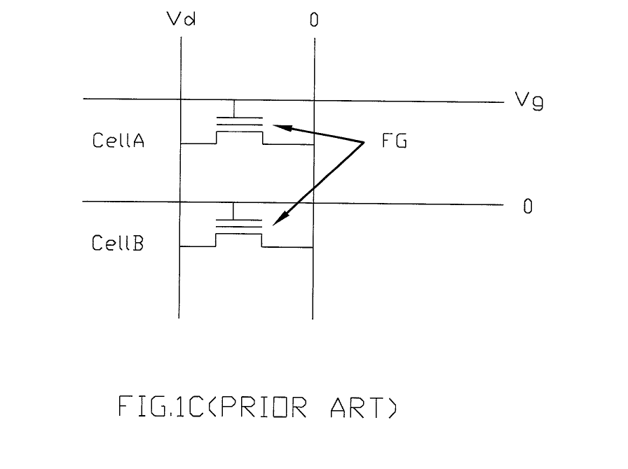

### DESCRIPTION OF THE PREFERRED EMBODIMENT

Preferred embodiments of the present invention will now be described in greater detail. Nevertheless, it should be recognized that the present invention can be practiced in a wide range of other embodiments besides those explicitly described, and the scope of the present invention is expressly not limited except as specified in the accompanying claims.

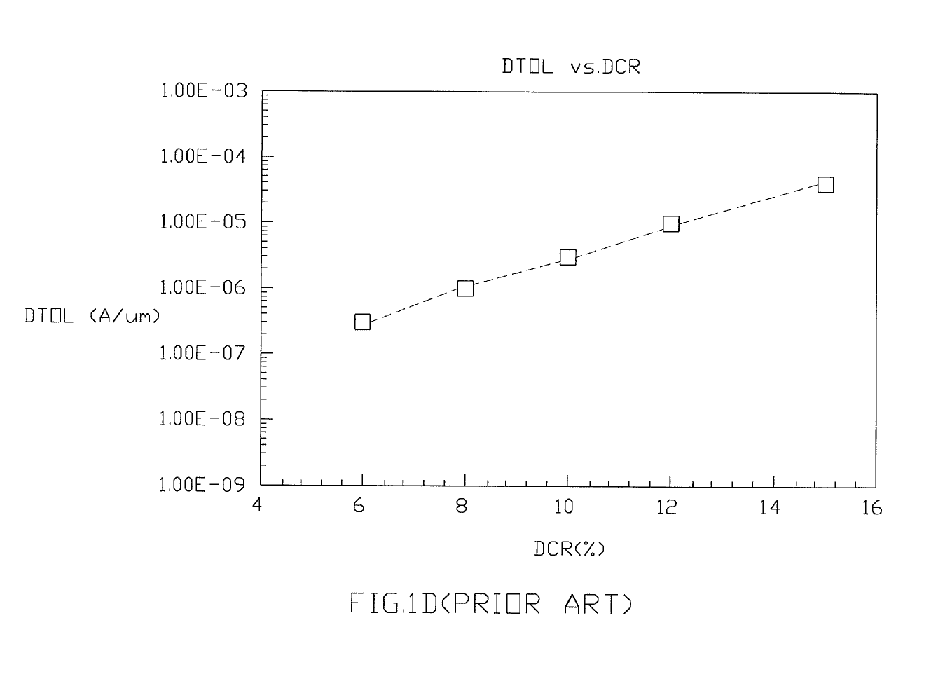

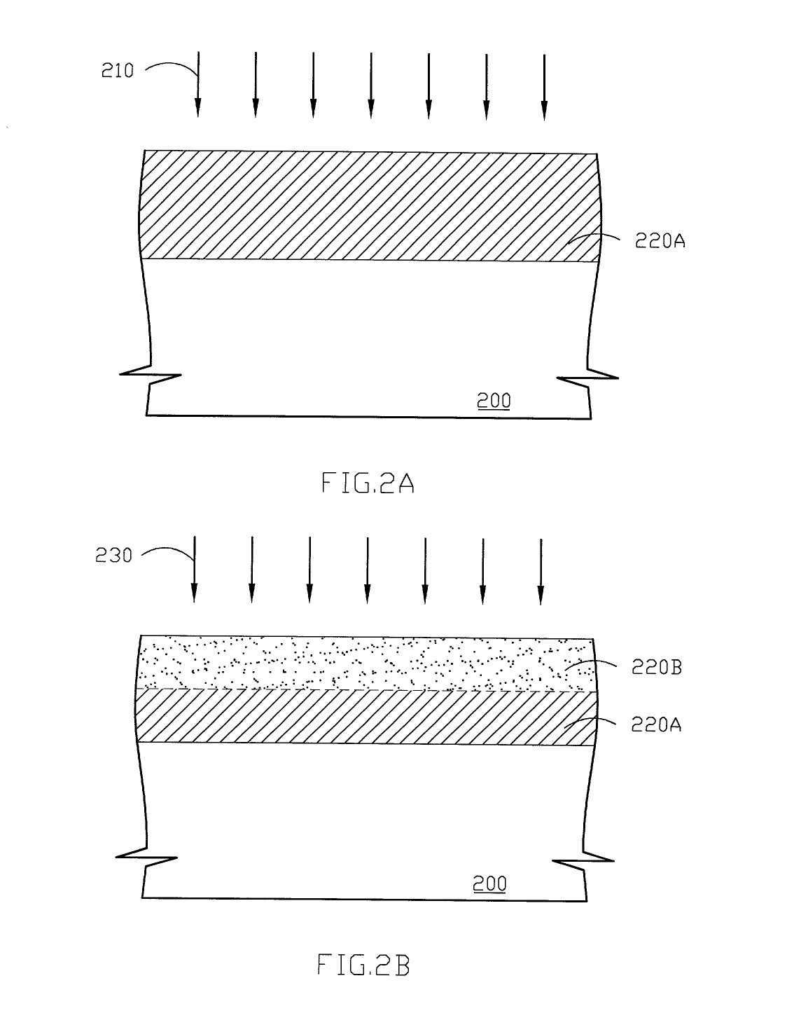

As illustrated in FIG. 2A to FIG. 2C, in the first embodiment of the present invention, first of all, a semiconductor substrate 200 is provided. Then a first ion-implanting process 210 is performed to form a first ion-implanting region 220A in the semiconductor substrate 200, wherein the first ion-implanting process 210 comprises: a first dopant, such as boron; a first dosage, such as 1E¹³ to 2.5E¹³; and a first energy, such as 150 KeV to 350 KeV. Next, a second ion-implanting process 230 is performed to intensify the first ion-implanting region 220A and form a second ion-implanting region 220B in the first ion-implanting region 220A, wherein the second ion-implanting process 230 comprises: a second dopant, such as boron; a second dosage, such as 3E¹³ to 6.5E¹³; and a second energy, such as 100 KeV to 150 KeV. Afterward, a third ion-implanting process 240 is performed to intensify the second ion-implanting region 220B and form a third ion-implanting region 220C in the second ion-implanting region 220B, wherein the third ion-implanting process 240 comprises: a third dopant, such as boron or boron fluoride (BF₂); a third dosage, such as 5E¹² to 25E¹²; and a third energy, such as 10 KeV to 70 KeV.

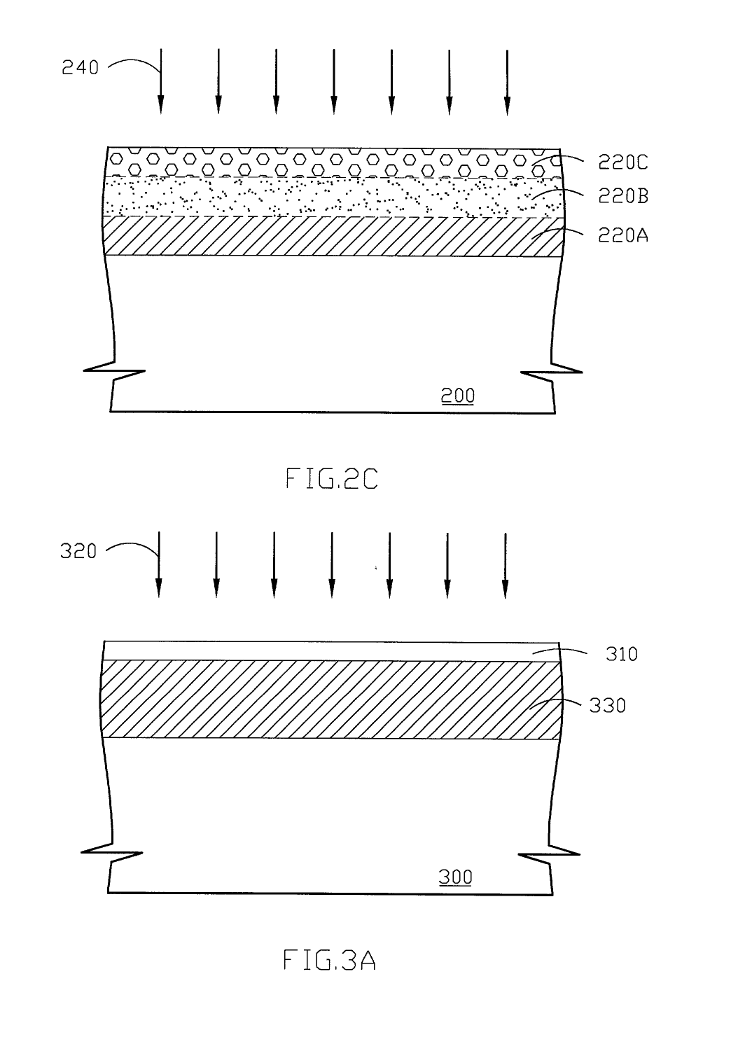

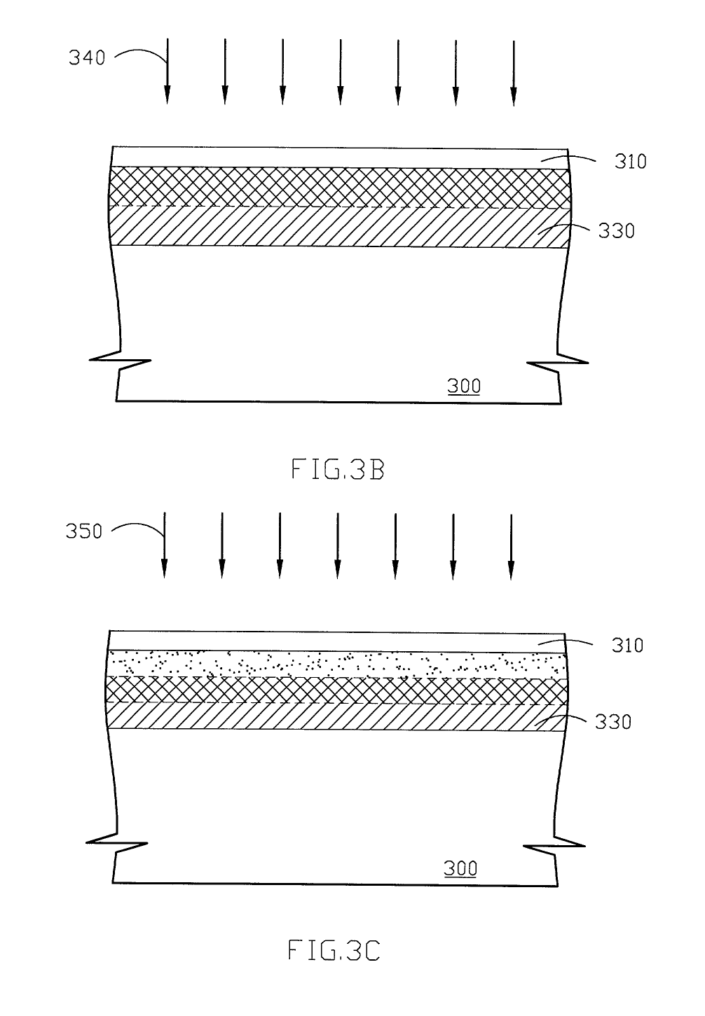

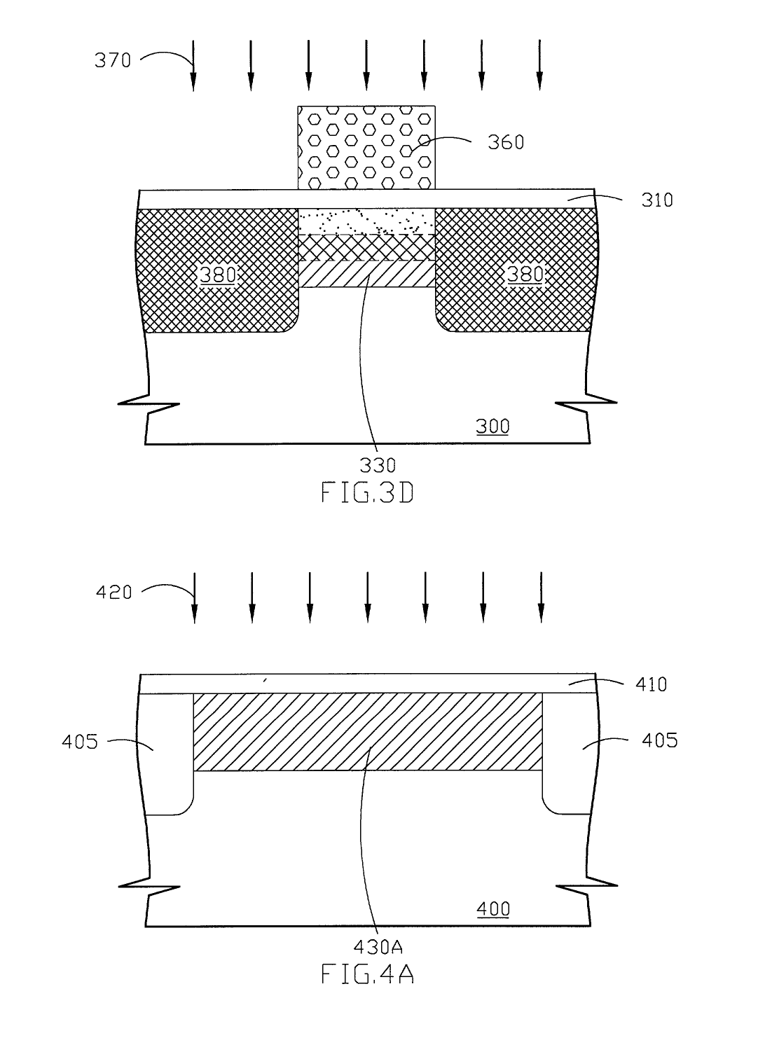

As illustrated in FIG. 3A to FIG. 3D, in the second embodiment of the present invention, first of all, a semiconductor substrate 300 that has a dielectric layer 310 thereon is provided. Then a first ion-implanting process 320 is performed to form an ion-implanting region 330 in the semiconductor substrate 300, wherein the first ion-implanting process 320 includes: a first dopant that comprises a boron; a first dosage that comprises the range about 1E¹³ to 2.5E¹³; and a first energy that comprises a range about 150 KeV to 350 KeV. Next, a second ion-implanting process 340 is performed to intensify the ion-implanting region 330 in the semiconductor substrate 300, wherein the second ion-implanting process 340 includes: a second dopant that comprises a boron; a second dosage that comprises a range about 3E¹³ to 6.5E¹³; and a second energy that comprises a range about 100 KeV to 150 KeV. Afterward, a third ion-implanting process 350 is performed to intensify the ion-implanting region 330 in the semiconductor substrate 300, wherein the third ion-implanting process 350 includes: a third dopant that comprises a boron; a third dosage that comprises a range about 5E¹² to 25E¹²; and a third energy that comprises a range about 20 KeV to 70 KeV. Furthermore, the third ion-implanting process 350 is used to adjust threshold voltage (Vt). Subsequently, a floating gate 360 is formed on the dielectric layer 310. Finally, a source/drain region 380 is formed in the ion-implanting region 330 of the semiconductor substrate 300 beside the bottom under the floating gate 360 by way of using a fourth ion-implanting process 370.

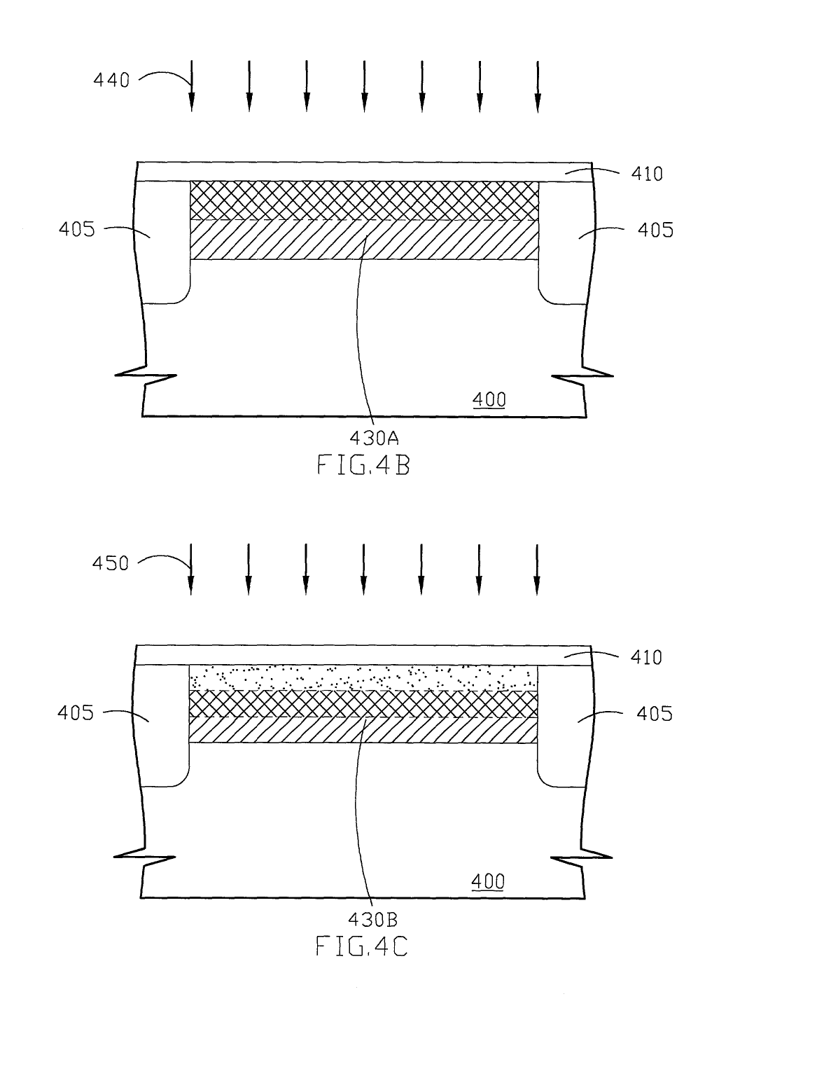

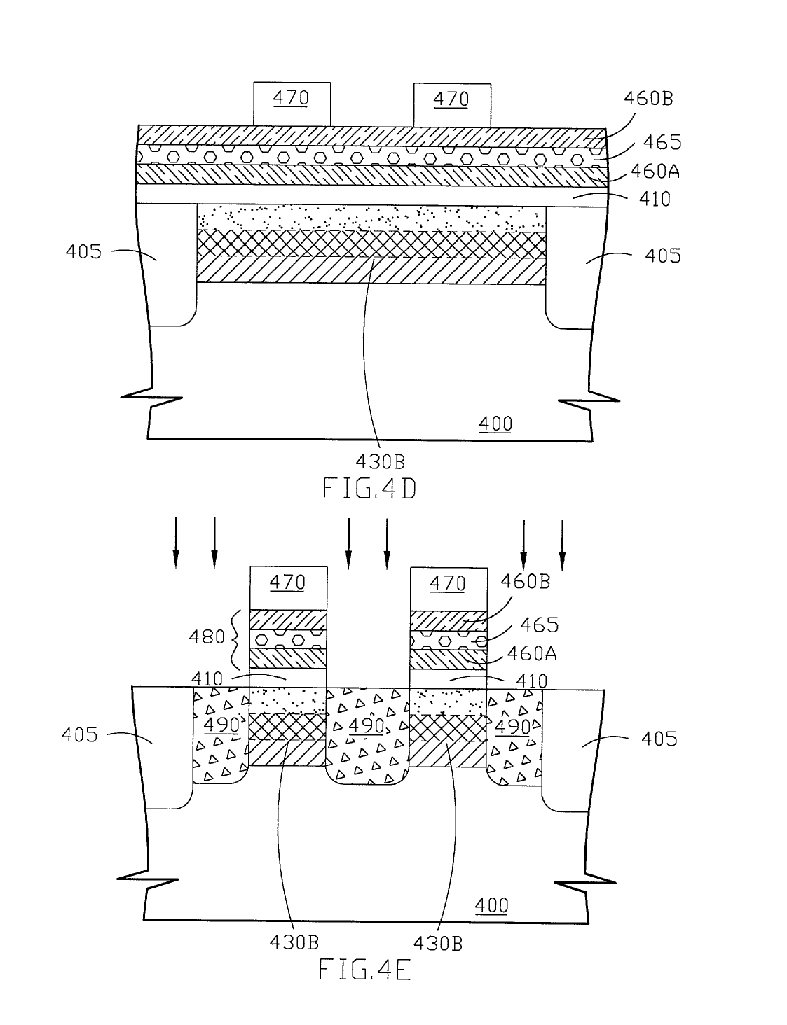

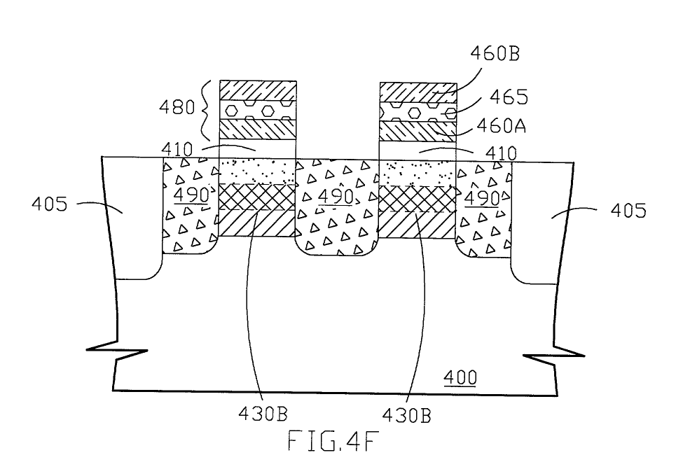

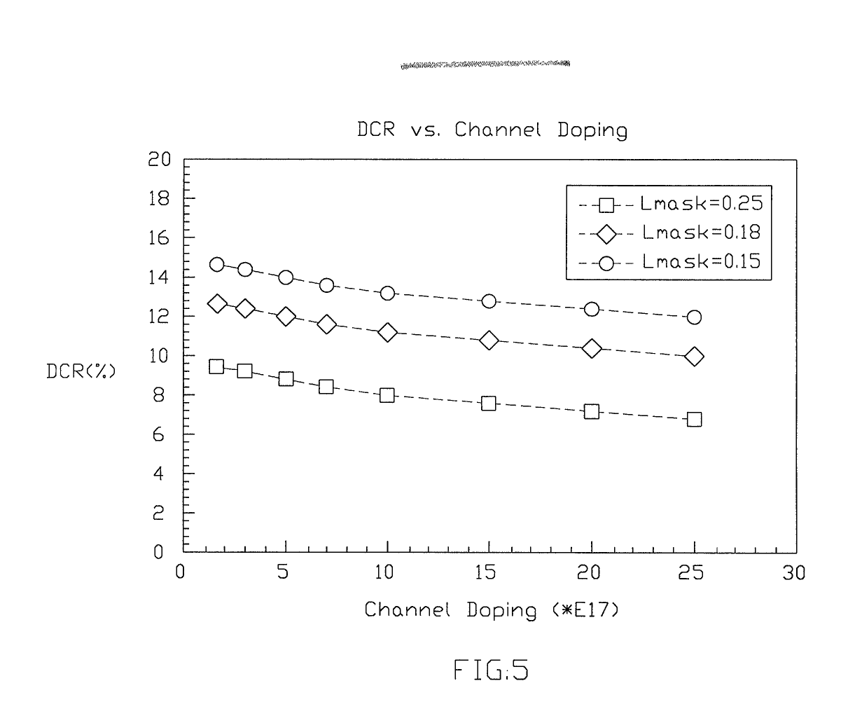

As illustrated in FIG. 4A to FIG. 4C, in the third embodiment of the present invention, first of all, a semiconductor substrate 400 is provided, wherein the semiconductor substrate 400 has a gate oxide layer 410 thereon and two insulated regions 405 that are individually located on the boundary of the semiconductor substrate 400. Then a first ion-implanting process 420 with a first energy about 150 KeV to 350 KeV is performed by way of using the boron-based dopant as a first dopant with a first dosage about 1E¹³ to 2.5E¹³ to form an ion-implanting region 430A in the semiconductor substrate 300 between two insulated regions 405. Next, a second ion-implanting process 440 with a second energy about 100 KeV to 150 KeV is performed by way of using the boron-based dopant as a second dopant with a second dosage about 3E¹³ to 6.5E¹³ to intensify the ion-implanting region 430A in the semiconductor substrate 400. Afterward, a third ion-implanting process 450 with a third energy about 10 KeV to 40 KeV is performed by way of using the boron-based dopant, such as boron fluoride, as a third dopant with a third dosage about 5E¹² to 25E¹² to intensify again the ion-implanting region 430A in the semiconductor substrate 400, so as to form a channel 430B with heavy dopant between two insulating regions, wherein the third ion-implanting process 450 is used to adjust threshold voltage (Vt).

Referring to FIG. 4D to FIG. 4F, in this embodiment, a first oxide layer 460A is formed on the gate oxide layer 410. Then a nitride layer 465 is formed on the first oxide layer 460A, and a second oxide layer 460B is formed on the nitride layer 465. Afterward, photoresist layers 470 are formed and defined on the second oxide layer 460B. Next, an etching process is performed by way of using the photoresist layers 470 as etching masks to etch the second oxide layer 460B, the nitride layer 465 and the first oxide layer 460A in turn until the semiconductor substrate 400, so as to form floating gates 480 having a stack of the second oxide layer 460B, the nitride layer 465 and the first oxide layer 460A on the gate oxide layer 410. Subsequently, a fourth ion-implanting process is performed by way of using the photoresist layers 470 as masks to form source/drain regions 490 in a partial of the channel 430B of the semiconductor substrate 400, wherein the source/drain regions 490 are separated from each other by the floating gates 480. Finally, the photoresist layers 470 are removed. Accordingly, this invention can form the floating gate devices 480 with small drain coupling ratio (DCR).

In these embodiments of the present invention, as discussed above, this invention can reduce the drain coupling ratio (DCR) by increasing the floating gate device's channel doping, so as to decrease the drain-turn-on leakage (DTOL). Furthermore, this invention can also fabricate highly integrated non-volatile memory by significantly scaling down the floating gate device, which will be an excellent candidate for next generation highly integrated flash memory. It is noted that when the channel doping is increased, the drain coupling ratio (DCR) will decrease, which is due to the smaller effective overlap area between the floating gate node and drain node. As shown in FIG. 5, the drain coupling ratio (DCR) of various channel doping are plotted. It reveals that higher channel doping will result in the smaller drain coupling ratio (DCR), therefore, the less drain-turn-on leakage (DTOL). In other words, increasing the channel doping will be an efficient way to reduce the drain-turn-on leakage (DTOL) because of the decreasing the drain coupling ratio (DCR). Therefore, the channel length of the floating gate device can be scaled without increasing the drain-turn-on leakage (DTOL). Therefore, the present invention can correspond to industrial economic effect, and the present invention is appropriate for deep sub-micron technology to provide the semiconductor devices.

Of course, it is possible to apply the present invention to the process for forming the floating gate of the flash memory, and also it is possible to apply the present invention to any process for forming the non-volatility memory. Also, this invention can be applied to reduce the drain coupling ratio (DCR) by increasing channel dopant concerning ion-implanting process for forming memories has not been developed at present. The present invention is the best the process for forming floating gate with small dimension compatible for deep sub-micro process.

Although specific embodiments have been illustrated and described, it will be obvious to those skilled in the art that various modifications may be made without departing from what is intended to be limited solely by the appended claims.

What is claimed is:

1. A method for forming a gate of non-volatility memory, the method comprising:
providing a semiconductor substrate, said semiconductor substrate has a dielectric layer thereon;
performing a first ion-implanting process to form a first ion-implanting region in said semiconductor substrate;
performing a second ion-implanting process to intensify said first ion-implanting region in said semiconductor substrate;
forming a gate on said dielectric layer; and
performing a third ion-implanting process to form a second ion-implanting region in a partial of said first ion-implanting region of said semiconductor substrate beside the bottom under said gate.

2. The method according to claim 1, wherein said first ion-implanting process comprises a boron-based dopant.

3. The method according to claim 1, wherein said first ion-implanting process comprises a dosage with a range about 1E¹³ to 2.5E¹³.

4. The method according to claim 1, wherein said first ion-implanting process comprises an energy with a range about 150 KeV to 350 KeV.

5. The method according to claim 1, wherein said second ion-implanting process comprises a boron-based dopant.

6. The method according to claim 1, wherein said second ion-implanting process comprises a dosage with a range about 3E¹³ to 6.5E¹³.

7. The method according to claim 1, wherein said second ion-implanting process comprises an energy with a range about 100 KeV to 150 KeV.

8. The method according to claim 1, wherein the method for forming said first ion-implanting region comprises a fourth ion-implanting process to intensify again said first ion-implanting region in said semiconductor substrate.

9. The method according to claim 8, wherein said fourth ion-implanting process comprises a boron-based dopant.

10. The method according to claim 8, wherein said fourth ion-implanting process comprises a dosage with a range about 5E¹² to 25E¹².

11. The method according to claim 8, wherein said fourth ion-implanting process comprises an energy with a range about 10 KeV to 70 KeV.

12. A method for forming an ion-implanting region with heavy dopant, the method comprising:
providing a semiconductor substrate;
performing a first ion-implanting process to form a first ion-implanting region in said semiconductor substrate;
performing a second ion-implanting process to form a second ion-implanting region in said first ion-implanting region of said semiconductor substrate; and
performing a third ion-implanting process to form a third ion-implanting region in said second ion-implanting region of said semiconductor substrate, so as to form said ion-implanting region with heavy dopand.

13. The method according to claim 12, wherein said first ion-implanting process comprises a dopant with the boron fluoride.

14. The method according to claim 12, wherein said first ion-implanting process comprises a dosage with a range about 1E¹³ to 2.5E¹³.

15. The method according to claim 12, wherein said first ion-implanting process comprises an energy with a range about 150 KeV to 350 KeV.

16. The method according to claim 12, wherein said second ion-implanting process comprises a dopant with the boron fluoride.

17. The method according to claim 12, wherein said second ion-implanting process comprises a dosage with a range about 3E¹³ to 6.5E¹³.

18. The method according to claim 12, wherein said second ion-implanting process comprises an energy with a range about 100 KeV to 150 KeV.

19. The method according to claim 12, wherein said third ion-implanting process comprises a boron-based dopant.

20. The method according to claim 12, wherein said third ion-implanting process comprises a dopant with the boron fluoride.

21. The method according to claim 12, wherein said third ion-implanting process comprises a dosage with a range about 5E¹² to 25E¹².

22. The method according to claim 12, wherein said third ion-implanting process comprises an energy with a range about 10 KeV to 70 KeV.

23. A method for forming a floating gate, the method comprising:
providing a semiconductor substrate, said semiconductor substrate has a gate oxide layer thereon;
performing a first ion-implanting process with a first energy about 150 KeV to 350 KeV by way of using a first dopant with based-boron to form a first ion-implanting region in said semiconductor substrate;
performing a second ion-implanting process with a second energy about 100 KeV to 150 KeV by way of using a second dopant with based-boron to intensify said first ion-implanting region in said semiconductor substrate;
performing a third ion-implanting process with a third energy about 20 KeV to 70 KeV by way of using a third dopant with based-boron to intensify again said first ion-implanting region in said semiconductor substrate, so as to form a channel with heavy dopant;
forming a floating gate on said gate oxide layer; and
performing a fourth ion-implanting process to form a second ion-implanting region in a partial of said first ion-implanting region of said semiconductor substrate beside the bottom under said floating gate, so as to serve the source/drain region.

24. The method according to claim 23, wherein said first ion-implanting process comprises a dosage with a range about 1E¹³ to 2.5E¹³.

25. The method according to claim 23, wherein said second ion-implanting process comprises a dosage with a range about 3E¹³ to 6.5E¹³.

26. The method according to claim 23, wherein said third ion-implanting process comprises a dosagewith a range about 5E¹² to 25E¹².

27. The method according to claim 23, wherein said third ion-implanting process comprises a third dopant with the boron fluoride.

28. The method according to claim 27, wherein said third ion-implanting process comprises a third energy with a range about 10 KeV to 40 KeV.

29. A method for forming a floating gate, the method comprising:
providing a semiconductor substrate, said semiconductor substrate has a gate oxide layer thereon;
performing a first ion-implanting process with a first energy about 150 KeV to 350 KeV by way of using a first dopant with the boron and a dosage about 1E¹³ to 2.5E¹³ to form a first ion-implanting region in said semiconductor substrate;
performing a second ion-implanting process with a second energy about 100 KeV to 150 KeV by way of using a second dopant with the boron and a dosage about 3E¹³ to 6.5E¹³ to intensify said first ion-implanting region in said semiconductor substrate;
performing a third ion-implanting process with a third energy about 10 KeV to 40 KeV by way of using a third dopant with the boron fluoride and a dosage about 5E¹² to 25E¹² to intensify again said first ion-implanting region in said semiconductor substrate, so as to form a channel with heavy dopant;
forming a floating gate on said gate oxide layer; and
performing a fourth ion-implanting process to form a second ion-implanting region in a partial of said first ion-implanting region of said semiconductor substrate beside the bottom under said floating gate, so as to serve the source/drain region.

30. The method according to claim 29, wherein said third ion-implanting process comprises a boron-based dopant.

31. The method according to claim 29, wherein said third ion-implanting process comprises an energy with a range about 20 KeV to 70 KeV.

32. A method for forming a plurality of floating gates of the flash memory, the method comprising:
providing a semiconductor substrate, said semiconductor substrate has a gate oxide layer thereon and two insulating regions that are located on boundary of said semiconductor substrate;
forming a channel region with heavy dopant in said semiconductor substrate between said two insulating regions;
forming a first oxide layer on said gate oxide layer;
forming a nitride layer on said first oxide layer;
forming a second oxide layer on said nitride layer;
forming and defining photoresist layers on said second oxide layer;
performing an etching process by way of using said photoresist layers as etching masks to etch said second oxide layer, said nitride layer and said first oxide layer in turn until said semiconductor substrate, so as to form floating gates on said gate oxide layer;
forming source/drain regions in a partial of said channel region of said semiconductor substrate by way of using said photoresist layers as implanting masks, wherein said source/drain regions are separated from each other; and
removing said photoresist layers to form said floating gates of said flash memory.

33. The method according to claim 32, wherein the method for forming said channel region comprise:
performing a first ion-implanting process with a first energy about 150 KeV to 350 KeV by way of using a first dopant with the boron and a dosage about 1E¹³ to 2.5E¹³ to form a first ion-implanting region in said semiconductor substrate;
performing a second ion-implanting process with a second energy about 100 KeV to 150 KeV by way of using a second dopant with the boron and a dosage about 3E¹³ to 6.5E¹³ to intensify said first ion-implanting region in said semiconductor substrate; and
performing a third ion-implanting process with a third energy about 10 KeV to 40 KeV by way of using a third dopant with the boron fluoride and a dosage about 5E¹² to 25E¹² to intensify again said first ion-implanting region in said semiconductor substrate, so as to form said channel region with heavy dopant.

34. The method according to claim 33, wherein said third ion-implanting process comprises a third dopant with the boron.

35. The method according to claim 33, wherein said third ion-implanting process comprises an energy that has a range about 20 KeV to 70 KeV.
